(19) United States
(12) Patent Application Publication
(10) Pub. No.: US 2026/0219579 A1
(43) Pub. Date: Jul. 30, 2026

(54) ILLUMINATION OPTICAL UNIT FOR PROJECTION LITHOGRAPHY, AND METHOD FOR MONITORING SUCH AN ILLUMINATION OPTICAL UNIT

(71) Applicant: Carl Zeiss SMT GmbH, Oberkochen (DE)

(72) Inventors: Michael RAMOLLA, Oberkochen (DE); Florian BAUMER, Oberkochen (DE); Martin ENDRES, Königsbronn (DE); Reimar FINKEN, Westhausen (DE)

(21) Appl. No.: 19/629,713

(22) Filed: Mar. 26, 2026

Related U.S. Application Data
(63) Continuation of application No. PCT/EP2024/075915, filed on Sep. 17, 2024.

(30) Foreign Application Priority Data
Oct. 4, 2023 (DE) 10 2023 209 699.4

(51) Int. Cl. G03F 7/00; G02B 26/08; H10P 76/00

(52) U.S. Cl. CPC G03F 7/70075; G03F 7/70116; G03F 7/70133; G02B 26/0833; H10P 76/00

(57) ABSTRACT

An illumination optical unit for projection lithography has a transfer facet mirror, an illumination specification facet mirror and a monitoring device. The latter has at least one spatially resolving monitoring sensor and a satellite facet, which belongs to the transfer facet mirror and is assigned to in each case exactly one monitoring transfer facet. The satellite facet is oriented in such a way that monitoring light from a monitoring light source is guided via the satellite facet and an illumination specification facet to be monitored, which is assigned to the monitoring transfer facet via an illumination channel, along a monitoring light channel to the monitoring sensor. The result is an illumination optical unit in which a tilting of illumination specification facets of an illumination specification facet mirror can be effectively monitored.

### CROSS-REFERENCE TO RELATED APPLICATIONS

The present application is a continuation of, and claims benefit under 35 USC 120 to, international application No. PCT/EP2024/075915, filed September 17, 2024, which claims benefit under 35 USC 119 of German Application No. 10 2023 209 699.4, filed October 4, 2023. The entire disclosure of each of these applications is incorporated by reference herein.

### FIELD

The disclosure relates to an illumination optical unit for projection lithography. Furthermore, the disclosure relates to a method for monitoring such an illumination optical unit, to an optical system comprising such an illumination optical unit, to a projection exposure apparatus comprising such an optical system, to a method for producing a microstructured or nanostructured component using such a projection exposure apparatus, and to a microstructured or nanostructured component produced using this method.

### BACKGROUND

An illumination optical unit for projection lithography is known from DE 102015208512 A1 and the references cited there.

### SUMMARY

The present disclosure seeks to develop an illumination optical unit of the type mentioned in the introduction in such a way that a tilting of illumination specification facets of an illumination specification facet mirror can be effectively monitored.

In an aspect, the disclosure provides an illumination optical unit for projection lithography. The illumination optical unit comprises a transfer facet mirror comprising a plurality of transfer facets for guiding illumination light from an illumination light source via illumination channels, which are specified by the transfer facets, along an illumination light beam path. The illumination optical unit also comprises an illumination specification facet mirror comprising a plurality of actuator-tiltable illumination specification facets for super-imposed guidance of the illumination light to an object field, in which an object to be illuminated is arrangeable, via the illumination channels via in each case one of the transfer facets and in each case an illumination specification facet assigned via the respective illumination channel. The illumination specification facet mirror is part of an optical unit via which the transfer facets are imaged at least into portions of the object field. The illumination optical unit further comprises a monitoring device. The monitoring device comprises at least one spatially resolving monitoring sensor and at least one satellite facet of the transfer facet mirror which is assigned to in each case exactly one of the transfer facets, which then constitutes a monitoring transfer facet, and is oriented in such a way that monitoring light from a monitoring light source is guided via the satellite facet and one of the illumination specification facets as the illumination specification facet to be monitored, which is assigned to the monitoring transfer facet via the illumination channel, along a monitoring light channel to the monitoring sensor.

According to the disclosure, it has been recognized that, when using at least one satellite facet, tiltings of the illumination specification facet to be monitored translate into corresponding displacements of the monitoring light channel which is guided via the respective satellite facet. These displacements of the monitoring light channel can be detected by sensor, and thus monitored, as corresponding displacements of a light channel location of incidence on the spatially resolving monitoring sensor of the monitoring device. Spatial differences between a target point of incidence of the monitoring light channel and an actual point of incidence of the monitoring light channel on the sensor can be a measure of tiltings of the illumination specification facet to be monitored. Especially mechanical and/or, given a corresponding actuator system of the illumination specification facet, capacitive and/or thermal drifts of the illumination specification facets can be effectively monitored by this approach. The monitoring light source can be identical to the illumination light source, i.e. the light source that generates the illumination light for projection lithography. The transfer facet mirror can be arranged in a field plane of a beam path of the illumination light. Parallel processing of a plurality of monitoring light channels and thus simultaneous monitoring of a plurality of illumination specification facets can be provided by the monitoring device of the illumination optical unit. The illumination specification facet mirror can be arranged in or near a pupil plane of a beam path of the illumination light. Alternatively, the illumination specification facet mirror can be arranged at a distance from a pupil plane of a beam path of the illumination light.

The transfer facets of the transfer facet mirror can be actuator-tiltable. This can be used for specifying a respective illumination channel for the illumination light which is guided to the object field via in each case one of the transfer facets and an illumination specification facet assigned to this transfer facet by way of a respective tilt position.

The at least one monitoring sensor of the monitoring device can provide a sensor area in the range of between 10 mm x 10 mm and 100 mm x 100 mm.

Especially the illumination light source that generates the illumination light can be used as a monitoring light source.

The monitoring device can include 10,000 satellite facets, for example.

In embodiments, the illumination optical unit comprises a plurality of satellite facets. This can help allow monitoring of a corresponding plurality of illumination specification facets to be monitored that are assigned to the satellite facets. Each illumination specification facet to be monitored can be assigned a satellite facet of the monitoring device via a corresponding monitoring transfer facet. Monitoring of especially all illumination specification facets of the illumination optical unit via corresponding satellite facets of the monitoring device is possible.

In embodiments, the satellite facet can be closely adjacent to the monitoring transfer facet respectively assigned thereto. Such a spatial proximity between the respective satellite facet and the monitoring transfer facet assigned thereto can help ensure that comparable causes of drift which arise for example on account of far field illumination of the transfer facet mirror can be monitored. A distance between the satellite facet and the monitoring transfer facet assigned thereto can correspond to a typical extension of a transfer facet. Insofar as the transfer facet mirror is embodied in a modular fashion, firstly the satellite facet and secondly the monitoring transfer facet assigned thereto can be selected in such a way that both facets belong to the same module of the transfer facet mirror.

In embodiments, the object field can have a longer field extension along a first field dimension and a shorter field extension along a second field dimension perpendicular thereto, wherein the at least one monitoring sensor is arranged at a distance from the object field along the first field dimension. Such an arrangement of the at least one monitoring sensor has proved to be desirable because of desired corresponding installation space properties. Two monitoring sensors can be arranged next to the respective shorter object field sides, i.e. next to the respective shorter field extensions of the object field, in such a way that the object field lies between the two monitoring sensors.

In embodiments, the monitoring light source can be embodied as a light source separate from an illumination light source, wherein the monitoring light is guided along a monitoring light beam path adjacent to the illumination channels via at least one of the satellite facets and the assigned illumination specification facet to be monitored. Such a design of the monitoring device with a separate monitoring light source can extend processing possibilities of the monitoring device. The monitoring light beam path of the separate monitoring light source can be coupled into a light guide of the illumination optical unit in the region of an intermediate focus. Alternatively or additionally, the illumination light source can be used as a monitoring light source.

In embodiments, the monitoring light has a plurality of wavelengths, and the at least one monitoring sensor is embodied as wavelength-selective. Such monitoring light of a plurality of wavelengths can help allow for parallel processing of the monitoring light channels assigned to these wavelengths. At least one spectrally selective monitoring sensor can be used in this case. Part of the wavelength-selective monitoring sensor can be a diffractive element, such as a grating. Alternatively or additionally, a wavelength-selective coating can belong to the wavelength-selective monitoring sensor, for example an interference coating. The monitoring sensor, then embodied as wavelength-selective, can have a wavelength-dependently acting filter. Such a monitoring sensor can be embodied in the style of a Bayer sensor, i.e. in the style of an image sensor operating according to the concept of a Bayer matrix. Pixels of such an image sensor can be assigned to different colours of a wavelength range to be covered, analogously to the RGB classification of the Bayer matrix.

In embodiments, the transfer facets can each be subdivided into a plurality of transfer individual mirrors, and/or the illumination specification facets can each be subdivided into a plurality of illumination specification individual mirrors. Such a transfer facet mirror and/or illumination specification facet mirror can be embodied as a MEMS mirror. The subdivision of the transfer facets and/or of the illumination specification facets into a plurality of individual mirrors, for example into a plurality of individual mirrors of a MEMS mirror device, can increase a flexibility of use of the illumination optical unit. The features of the monitoring device can be particularly pronounced when monitoring illumination specification facets which in turn are constructed from a plurality of illumination specification individual mirrors.

In some embodiments, the at least one satellite facet can be actuator-tiltable, wherein the monitoring device has a monitoring scanning unit, which is signal-connected to an actuator system for tilting the at least one satellite facet. With the aid of such a monitoring device, an effective tilt position monitoring of all illumination specification individual mirrors which belong to an illumination specification facet is possible. In this case, these illumination specification individual mirrors can be scanned via the monitoring scanning unit.

In embodiments, the monitoring light source can be embodied as a light source grid embodied in a manner adapted to a grid of illumination specification individual mirrors, each forming an illumination specification facet. Such an embodiment of the monitoring light source as a light source grid can help allow parallel processing for detecting tiltings of illumination specification individual mirrors of an illumination specification facet to be monitored as an alternative or additional possibility for monitoring instead of the abovementioned monitoring scanning unit. In the case of the light source grid, parallel processing by the monitoring device is then possible.

In an aspect, the disclosure provides a method for monitoring an illumination optical unit according to the disclosure. The method comprises the following steps: assigning satellite facets to the illumination specification facets to be monitored; guiding monitoring light along at least one monitoring light channel via the respective satellite facet and the assigned illumination specification facet to be monitored; measuring an actual point of incidence of the respective monitoring light channel on the monitoring sensor; and comparing the actual point of incidence with a predetermined target point of incidence of the respective monitoring light channel.

Features of a monitoring method according to the disclosure can correspond to those which have been explained above with reference to the illumination optical unit comprising the monitoring device. The monitoring of the illumination specification facets to be monitored can take place sequentially and/or in parallel. For monitoring, it is possible to use a monitoring scanning unit for sequentially monitoring corresponding illumination specification facets and/or illumination specification individual mirrors, as already explained above. For monitoring, it is possible to implement a light source grid of a monitoring light source, as likewise already explained above, for parallel tilt position monitoring of a plurality of illumination specification facets and/or of a plurality of illumination specification individual mirrors. For comparing, cross-correlation techniques can be used in the context of the monitoring method.

The monitoring method can be carried out in parallel with the used operation of the illumination optical unit. Alternatively or additionally, the monitoring method can be carried out during pauses in operation of the projection exposure apparatus to which the illumination optical unit belongs. The monitoring method can be used to monitor especially static alignment errors, manufacturing or indication faults and also general incorrect positions of the illumination specification facets to be monitored. Alternatively or additionally, dynamic tilt position deviations can be monitored, for example an effect of thermal effects and/or a change in the illumination specification facets or a facet actuator system due to the period of use.

For measuring and comparing the points of incidence, diffraction effects that may occur along the monitoring light channels can be taken into account.

In embodiments, the method comprises, for assigning: maintaining a minimum distance between predetermined target points of incidence of different monitoring light channels on the monitoring sensor; and/or not exceeding a maximum distance between the respective satellite facet and the monitoring transfer facet assigned thereto, which is assigned to the illumination specification facet to be monitored via an illumination channel. Such assignment methods can specify constraints that can improve a quality of the monitoring result. Insofar as a minimum distance between predetermined target points of incidence of different monitoring light channels on the monitoring sensor is maintained, the corresponding monitoring light channels can be reliably kept apart during evaluation of the comparison result of the monitoring method and can thus be uniquely assigned to the satellite facets and thus to the illumination specification facets to be monitored. Insofar as a maximum distance between the satellite facet and the monitoring transfer facet assigned thereto is maintained, it can be ensured that distance-related deviations between the tilt position influences on the satellite facet, firstly, and on the monitoring transfer facet assigned thereto, secondly, are not undesirably high.

In an aspect, the disclosure provides an optical system comprising an illumination optical unit according to the disclosure and a projection optical unit for imaging the object field into an image field, in which a substrate is arrangeable. In an aspect, the disclosure provides an optical system comprising an illumination optical unit according to the disclosure and a monitoring light source. In an aspect, the disclosure provides a projection exposure apparatus comprising such an optical system and an illumination light source. In an aspect, the disclosure provides a method for producing a microstructured component comprising the following method steps: providing a reticle; providing a wafer having a coating that is sensitive to the illumination light; projecting at least one portion of the reticle onto the wafer with the aid of the projection exposure apparatus according to the disclosure; and developing the light-sensitive layer exposed with the illumination light on the wafer. In an aspect, the disclosure provides a component produced according to such a method. Features of such aspects can correspond to those which have already been explained above with reference to an illumination optical unit according to the disclosure and/or to a monitoring method according to the disclosure.

The substrate can be a wafer. The component can be, for example, a structured semiconductor component, for example a microchip, such as a memory chip.

### BRIEF DESCRIPTION OF THE DRAWINGS

Exemplary embodiments of the disclosure are explained in more detail below with reference to the drawing, in which:

FIG. 1 shows very schematically, in meridional section, a projection exposure apparatus for EUV microlithography, comprising a light source, an illumination optical unit and a projection optical unit, wherein a plan view of an object field of the projection exposure apparatus is illustrated in an insert;

FIG. 2 shows schematically and likewise in meridional section a beam path of selected individual rays of illumination light within the illumination optical unit according to FIG. 1, proceeding from an intermediate focus through to a reticle or object arranged in the object plane of the projection optical unit in the region of the illumination or object field;

FIG. 3 shows a plan view of a first facet mirror of the illumination optical unit, which is arranged in a field plane of the illumination optical unit and in an illumination far field of the light source and which is also referred to as a transfer facet mirror or as a field facet mirror, wherein an array arrangement of individual mirror units, in each case formed from a sub-array, not visible in FIG. 3, of individual mirrors of the first facet mirror, is illustrated;

FIG. 4 shows, still schematically but in comparison with FIG. 3 in an enlarged, exemplary and more detailed manner, one of the individual mirror units embodied as a sub-array of the individual mirrors;

FIG. 5 shows a plan view of an illumination specification facet mirror of the illumination optical unit, the mirror being arranged at a distance from a pupil plane of the illumination optical unit and also being referred to as second facet mirror;

FIG. 6 shows schematically the illumination optical unit of the projection exposure apparatus including a monitoring device, wherein an illumination channel for illuminating the object via a transfer facet of the transfer facet mirror and an illumination specification facet of the illumination specification facet mirror is illustrated in a dotted depiction and a monitoring light channel for impinging on a monitoring sensor of the monitoring device via a satellite facet of the transfer facet mirror and the illumination specification facet of the illumination channel is illustrated in a solid-line depiction;

FIG. 7 shows a further embodiment of the illumination optical unit with components of a further embodiment of the monitoring device, comprising, separate from the light source for the illumination light, a monitoring light source for monitoring light which is guided along a monitoring light channel via a satellite facet of the transfer facet mirror;

FIG. 8 shows in a perspective view a further embodiment of the illumination optical unit with a further embodiment of the monitoring device, comprising three monitoring light sources, each of which generates monitoring light of a specific wavelength, wherein the wavelengths generated by the monitoring light sources differ from one another;

FIG. 9 shows, in an illustration similar to FIG. 6, a further embodiment of the monitoring device with a monitoring scanning unit, which is signal-connected to an actuator system of the satellite facet highlighted in FIG. 9;

FIG. 10 shows, in an illustration similar to FIG. 3, a plan view of the transfer facet mirror, highlighting a distribution of transfer individual mirrors used for illumination of the object with a specific illumination setting and transfer individual mirrors not used for this illumination, which are distributed in each case on a total used area of the transfer facet mirror;

FIG. 11 shows in a plan view the in this case rectangular object field of the projection exposure apparatus and to the right and left thereof a respective sensor area of a spatially resolving monitoring sensor of the monitoring device, wherein points of incidence of monitoring light channels in the manner of the monitoring light channel according to FIG. 6 on the sensor areas are illustrated schematically;

FIG. 12 shows one of the sensor areas of the monitoring device, wherein a distribution of points of incidence of the monitoring light channels in the manner of FIG. 11 after carrying out a method of assignment of satellite facets to illumination specification facets to be monitored is illustrated, wherein the assignment method leads to a sufficient spatial distance between the points of incidence;

FIG. 13 shows, in an illustration similar to that according to FIG. 9, an embodiment of the monitoring device with a monitoring light source embodied as a light source grid, wherein all light sources of the light source grid are activated and wherein a monitoring light channel of the monitoring device, proceeding from a centre of the light source grid, is illustrated; and

FIG. 14 shows, in an illustration similar to FIG. 13, an operating situation of the monitoring device according to FIG. 13, wherein exclusively a single light source of the light source grid is active.

### DETAILED DESCRIPTION

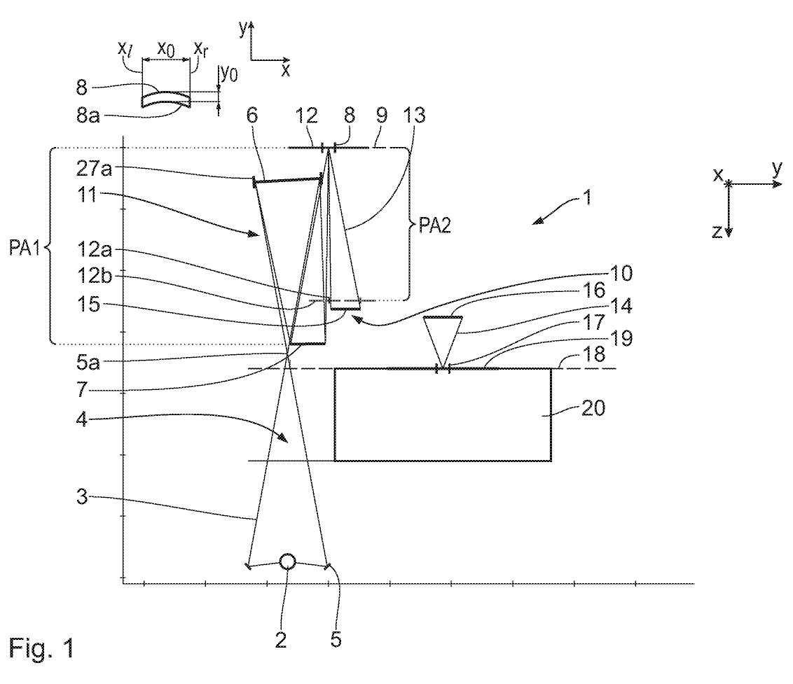

A microlithographic projection exposure apparatus 1 illustrated highly schematically and in meridional section in FIG. 1 has a light source 2 for illumination light 3. The light source 2 is an EUV light source which generates light in a wavelength range of between 5 nm and 30 nm. This can be an LPP (laser produced plasma) light source, a DPP (discharge produced plasma) light source or a synchrotron radiation-based light source, for example a free electron laser (FEL).

A transfer optical unit 4 is used to guide the illumination light 3, proceeding from the light source 2. The transfer optical unit has a collector 5, which is illustrated only with regard to its reflective effect in FIG. 1, and a transfer facet mirror 6, which is described in even greater detail below and which is also referred to as first facet mirror or as field facet mirror. An intermediate focus 5a of the illumination light 3 is arranged between the collector 5 and the transfer facet mirror 6. A numerical aperture of the illumination light 3 in the region of the intermediate focus 5a is NA = 0.182, for example. An illumination specification facet mirror 7, which is also referred to as second or further facet mirror and is likewise explained in even greater detail below, is disposed downstream of the transfer facet mirror 6 and thus the transfer optical unit 4. The optical components 5 to 7 are constituent parts of an illumination optical unit 11 of the projection exposure apparatus 1.

The transfer facet mirror 6 is arranged in a field plane of the illumination optical unit 11.

The illumination specification facet mirror 7 of the illumination optical unit 11 is arranged at a distance from pupil planes of the illumination optical unit 11. Such an arrangement is also referred to as specular reflector. Alternatively, the illumination specification facet mirror 7 can also be arranged in the region of a pupil plane of the illumination optical unit 11, and it is referred to as a pupil facet mirror in that case.

A reticle 12 is disposed downstream of the illumination specification facet mirror 7 in the beam path of the illumination light 3 and arranged in an object plane 9 of a downstream projection optical unit 10 of the projection exposure apparatus 1. The projection optical unit 10 is a projection lens. The illumination optical unit 11 is used to illuminate an object field 8 on the reticle 12 in the object plane 9 in a defined manner. The object field 8 simultaneously constitutes an illumination field of the illumination optical unit 11. Generally it holds true that the illumination field is formed in such a way that the object field 8 can be arranged in the illumination field.

Like the transfer facet mirror 6 as well, the illumination specification facet mirror 7 is part of a pupil illumination unit of the illumination optical unit and serves to illuminate an entrance pupil 12a in a pupil plane 12b of the projection optical unit 10 with the illumination light 3 with a specified pupil intensity distribution. The entrance pupil 12a of the projection optical unit 10 can be arranged in the illumination beam path upstream of the object field 8 or else downstream of the object field 8.

FIG. 1 shows the case in which the entrance pupil 12a is arranged in the illumination beam path downstream of the object field 8. A pupil distance PA between the second facet mirror 7 and the pupil plane 12b results in this case as the sum of a z-distance PA1 between the second facet mirror 7 and the object plane 9 and the z-distance PA2 between the object plane 9 and the pupil plane 12b. It thus holds true that: PA = PA1 + PA2. Alternatively, the pupil distance PA can also be measured in the beam direction.

In order to facilitate the representation of positional relationships, a Cartesian xyz-coordinate system is used hereinafter. The x-direction runs perpendicularly to the plane of the drawing into the latter in FIG. 1. The y-direction runs towards the right in FIG. 1. The z-direction runs downwards in FIG. 1. Coordinate systems used in the drawing have x-axes running parallel to one another in each case. The course of a z-axis of the coordinate systems follows a respective principal direction of the illumination light 3 within the figure respectively under consideration.

The object field 8 has an arcuate or partly circular shape and is delimited by two mutually parallel circle arcs and two straight side edges which run in the y-direction with a length y₀ and are at a distance x₀ from one another in the x-direction. The aspect ratio x₀/y₀ is 13 to 1. An insert in FIG. 1 shows a plan view of the object field 8, this plan view not being true to scale. A boundary shape 8a is arcuate. In an alternative and likewise possible object field 8, the boundary shape thereof is rectangular, likewise with aspect ratio x₀/y₀.

The reticle 12 is displaced through the object field 8 along an object displacement direction y during a projection exposure.

The projection optical unit 10 is indicated only in part and highly schematically in FIG. 1. An object field-side numerical aperture 13 and an image field-side numerical aperture 14 of the projection optical unit 10 are illustrated. The image field-side numerical aperture 14 can be in the range of between 0.2 and 0.8 and can be 0.3, 0.33, 0.4, 0.45, 0.5, 0.55, 0.6, 0.65, 0.7 or else 0.75, for example. Further optical components (not illustrated in FIG. 1) of the projection optical unit 10 for guiding the illumination light 3 between indicated optical components 15, 16 of the projection optical unit 10 are situated between these optical components 15, 16, which can be embodied for example as mirrors that are reflective for the EUV illumination light 3.

The projection optical unit 10 images the object field 8 into an image field 17 in an image plane 18 on a wafer 19, which, like the reticle 12 as well, is carried by a holder (not illustrated in more specific detail). Both the reticle holder and the wafer holder are displaceable both in the x-direction and in the y-direction via corresponding displacement drives. An installation space of the wafer holder is illustrated as a rectangular box at 20 in FIG. 1. The installation space 20 is cuboid with an extent in x-, y- and z-directions that is dependent on the components to be accommodated herein. The installation space 20 has, for example, proceeding from the centre of the image field 17, an extension of 1 m in the x-direction and in the y-direction. In the z-direction, too, the installation space 20 has, proceeding from the image plane 18, an extension of 1 m, for example. The illumination light 3 has to be guided in the illumination optical unit 11 and the projection optical unit 10 in such a way that it is in each case guided past the installation space 20.

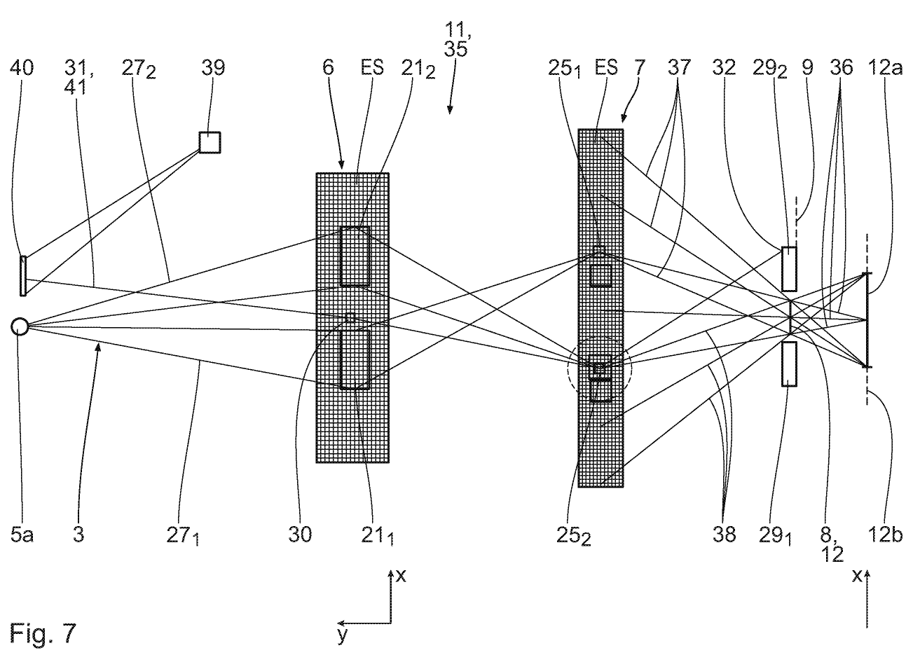

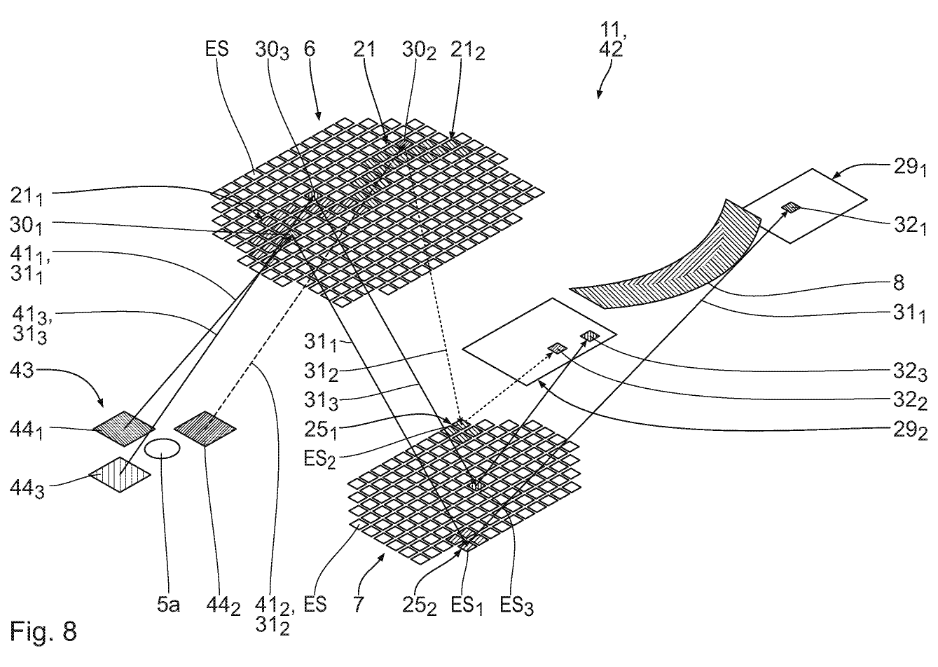

The transfer facet mirror 6 has a multiplicity of transfer facets 21, which are also referred to as first facets. The transfer facet mirror 6 can be embodied as a MEMS mirror. The transfer facets 21 are transfer individual mirrors ES (cf. FIGS. 7 and 8, for example) which are switchable at least between two tilt positions and which are embodied as micromirrors. The transfer facets 21 can be embodied as micromirrors tiltable in a driven manner about two rotation axes perpendicular to one another.

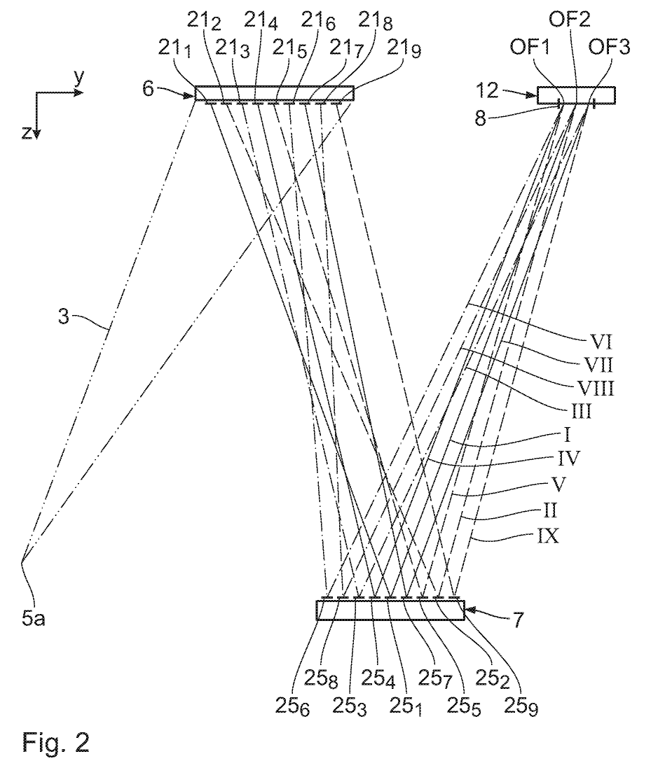

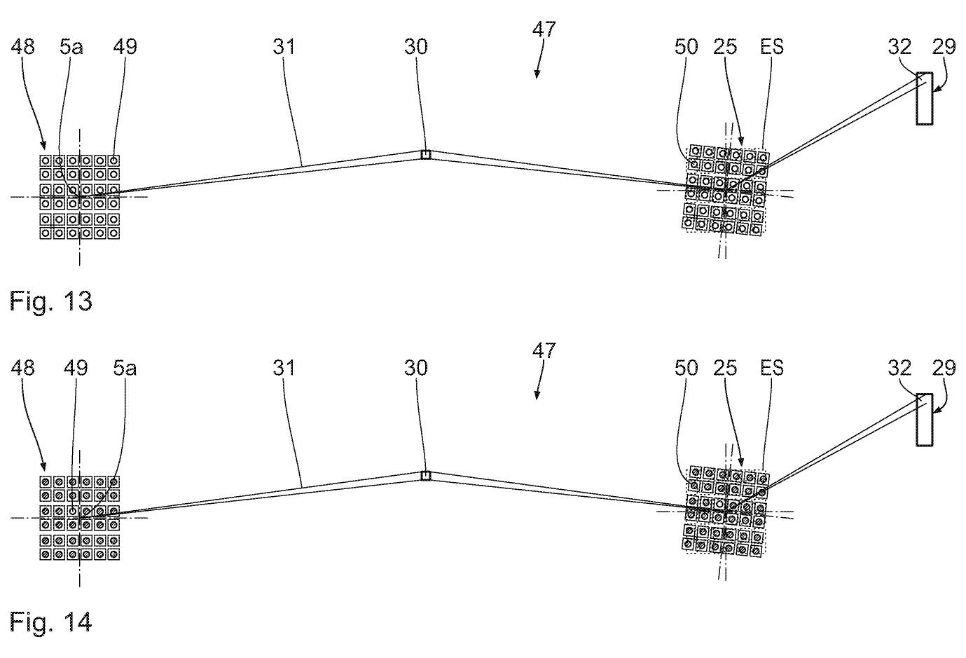

Of these transfer facets 21, a line having a total of nine transfer facets 21 is illustrated schematically in the yz-sectional view according to FIG. 2, the transfer facets being indexed from left to right by 21₁ to 21₉ in FIG. 2. In actual fact, the transfer facet mirror 6 has a significantly greater multiplicity of the transfer facets 21. The transfer individual mirrors ES are grouped into the transfer facets 21 (in this respect, cf. also FIGS. 7 and 13, for example). These transfer facets 21 are also referred to as individual mirror groups, as virtual field facets or as virtual facet groups.

Each of the transfer facets 21 guides a component of the illumination light 3, which is also referred to as illumination light component beam, via an illumination channel for partial or complete illumination of the object field 8. Via the illumination channel and an illumination light component beam 3ᵢ guided via the latter, exactly one illumination specification facet 25 of the illumination specification facet mirror 7 is assigned in each case to one of the individual mirror groups or transfer facets 21. In principle, each of the illumination specification facets 25 can for its part in turn be constructed from a plurality of individual mirrors ES (cf. FIG. 7, for example). The illumination specification facets 25 are also referred to hereinafter as second facets. In so far as the second facet mirror 7 is arranged in the region of a pupil plane of the illumination optical unit 11, the illumination specification facets 25 are also referred to as pupil facets.

An individual mirror group or transfer facet 21 is a group of individual mirrors ES of the first facet mirror 6 which is imaged into the object field 8 by the same second facet 25.

For further details of possible embodiments of the transfer facet mirror 6 and the projection optical unit 10, reference is made to WO 2010/099 807 A.

The illumination specification facet mirror 7 is part of an optical unit via which transfer facets 21 are imaged at least into portions or partial fields of the object field 8. At least some of the illumination specification facets 25 possibly illuminate only a partial zone or partial field of the object field 8. The partial fields are shaped very individually and, moreover, depend on the desired illumination direction distribution (pupil shape) in the object field 8, i.e. the illumination setting. The illumination specification facets 25 are therefore illuminated by very differently shaped virtual field facets, the shape of which corresponds precisely to the shape of the respective partial field to be illuminated. Moreover, each illumination specification facet 25 contributes to different regions of the pupil depending on the location in the object field 8.

The illumination specification facet mirror 7 can be embodied as a MEMS mirror, especially if each of the illumination specification facets 25 is constructed from a plurality of individual mirrors ES. The illumination specification facets 25 are micromirrors switchable between at least two tilt positions. The illumination specification facets 25 are embodied as micromirrors which are two-dimensionally tiltable and tiltable in a driven manner about two mutually perpendicular tilt axes, for example in continuous and independent fashion, i.e. the micromirrors can be positioned into a multiplicity of different tilt positions.

One example of a specified assignment of individual transfer facets 21 to the illumination specification facets 25 is illustrated in FIG. 2. The illumination specification facets 25 in each case assigned to the transfer facets 21₁ to 21₉ are indexed according to this assignment. On account of this assignment, the illumination specification facets 25 are illuminated from left to right in the following order: 25₆, 25₈, 25₃, 25₄, 25₁, 25₇, 25₅, 25₂and 25₉.

The indices 6, 8 and 3 of the facets 21, 25 include three illumination channels VI, VIII and III which illuminate three object field points OF1, OF2, OF3 from a first illumination direction, the object field points being numbered from left to right in FIG. 2. The indices 4, 1 and 7 of the facets 21, 25 pertain to three further illumination channels IV, I, VII which illuminate the three object field points OF1 to OF3 from a second illumination direction. The indices 5, 2 and 9 of the facets 21, 25 pertain to three further illumination channels V, II, IX which illuminate the three object field points OF1 to OF3 from a third illumination direction. The illumination channels I to IX are assigned corresponding illumination light component beams 3₁ to 3₉.

The illumination directions assigned to
the illumination channels VI, VIII, III,
the illumination channels IV, I, VII and
the illumination channels V, II, IX

are identical in each case. The assignment of the transfer facets 21 to the illumination specification facets 25 is therefore such that this results in a telecentric illumination of the object field 8 in the case of the illumination example illustrated pictorially.

The object field 8 can be illuminated via the transfer facet mirror 6 and the illumination specification facet mirror 7 in the style of a specular reflector. The principle of the specular reflector is known from US 2006/0132747 A1.

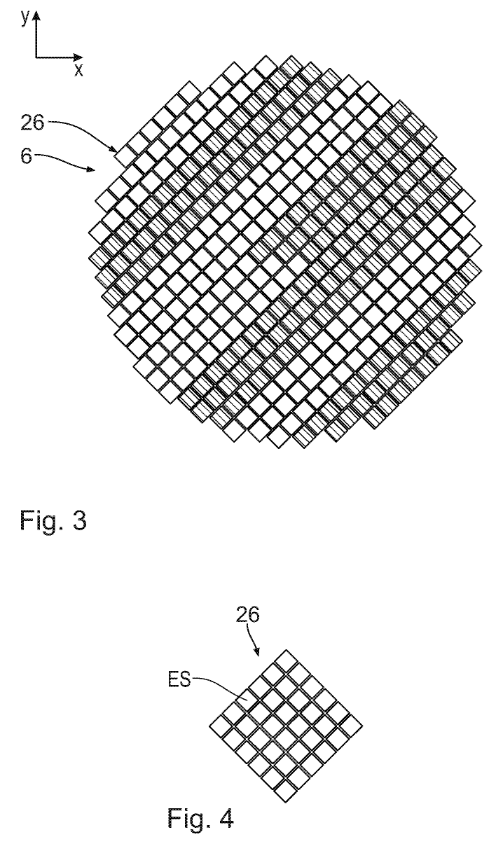

FIG. 3 shows a plan view of one embodiment of the first facet mirror 6. The latter has a regular array arrangement of individual mirror units 26, which are bounded by squares in FIG. 3. Each of the individual mirror units 26 is embodied as a sub-array of N x M of the individual mirrors ES. This sub-array has a plurality of array lines which extend along a line direction that corresponds to an angle bisector of the xy-coordinate system.

Some of the mutually adjacent array lines are mutually offset from one another by a proportion of an extension of one of the individual mirror units 26, for example by half of this extension of the respective individual mirror unit 26 along the array line. Depending on the embodiment of the facet mirror 6, it is possible to manage entirely without such an offset, and so this results in an array arrangement constructed entirely of lines and columns. Alternatively, all array lines can be offset from one another. Different absolute offset values between different adjacent array parts are also possible, depending on the embodiment of the facet mirror 6 and depending on the desired properties for positioning of the individual mirror units 26.

The first facet mirror 6 is embodied for arrangement in a used region of a far field of the light source 2.

FIG. 4 shows one of the individual mirror units 26, still schematically but with more detail. The illustration shows a subdivision of the individual mirror unit 26 into the sub-array of 6 x 6 of the individual mirrors ES in this case. Each of the individual mirror units 26 thus has 36 of the individual mirrors ES in the embodiment illustrated. N = 6 and M = 6 thus applies to the N x M sub-array arrangement in the example according to FIG. 4. N and M can be the same, can be different and can each be in the range of between 2 and 64, for example 4, 8, 16, 32 or 64. Values other than powers of two are also possible for N and M, for example 25 or 50. For example, a 12 x 12 or 24 x 24 sub-array is also possible.

In the embodiment illustrated in FIG. 3, the first facet mirror 6 has an arrangement of the individual mirror units 26 within a circular envelope. Alternatively, the first facet mirror 6 can also comprise the individual mirror units 26 within an envelope with an elliptical, rectangular or else polygonal boundary.

In each case one of the individual mirror units 26 can include a plurality of complete or partial individual mirror groups, which guide the illumination light 3 to different second facets 25 and which are imaged into the object field 8 in a manner superimposed on one another. The individual mirror groups, i.e. the transfer facets 21, can extend over a plurality of the individual mirror units 26.

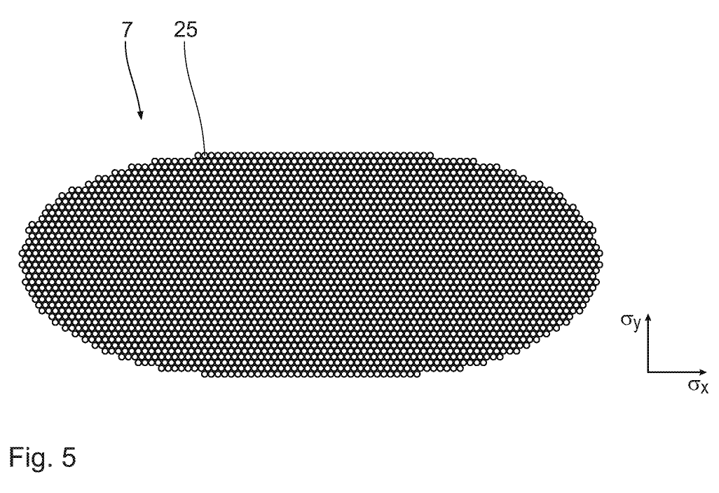

FIG. 5 shows, once again in a plan view, one embodiment of the second facet mirror 7.

The second facets 25 of the second facet mirror 7 are each embodied with a circular boundary and are present in hexagonal close-packed form. Second facets 25 with a rectangular or polygonal boundary, for example a hexagonal boundary, are also an alternative to second facets 25 with a circular boundary. The second facets 25 can be embodied in turn as individual mirror units in the style of the individual mirror units of the first facet mirror 6 and can be subdivided into a plurality of individual mirrors in the style of the individual mirrors ES in this case. In principle, with regard to the subdivision into individual mirrors and individual mirror units, a structure of the second facet mirror 7 can correspond to the structure of the first facet mirror 6.

In the embodiment according to FIG. 5, each of the second facets 25 can also be embodied as a monolithic facet.

In the second facet mirror 7, the second facets 25 are arranged within an envelope with an elliptical boundary. Alternatively, other envelope shapes are also possible here, for example a circular envelope, a rectangular envelope and also an envelope with a polygonal boundary.

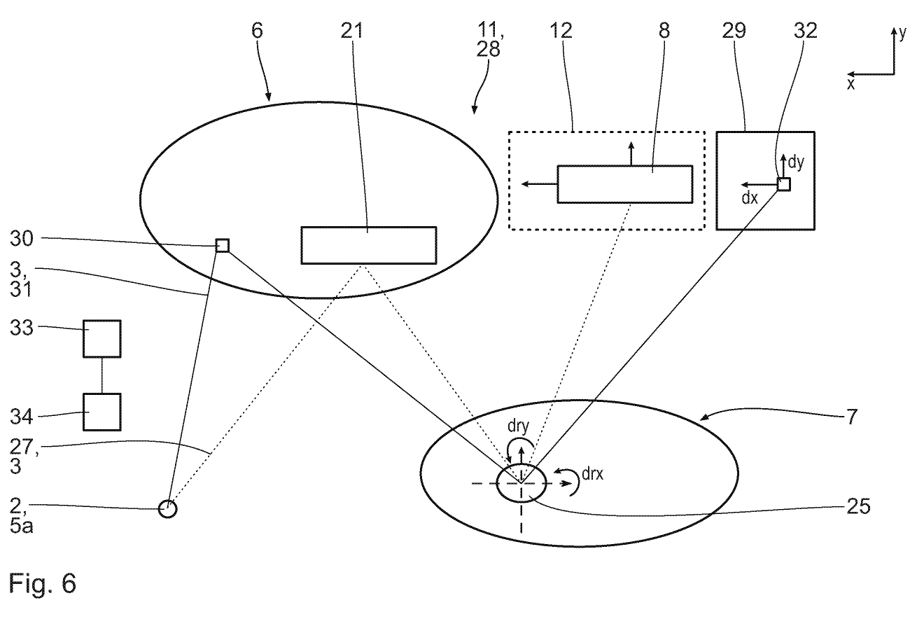

FIG. 6 schematically shows one embodiment of the illumination optical unit 11. Components and functions corresponding to those which have already been explained above with reference to FIGS. 1 to 5 bear the same reference signs and will not be discussed in detail again.

FIG. 6 illustrates in a dotted depiction a course of an illumination channel 27 between the light source 2 or the intermediate focus 5a, a selected transfer facet 21 of the transfer facet mirror 6, an illumination specification facet 25 assigned to this transfer facet 21, and the object field 8 on the reticle 12. The illumination specification facet 25 is assigned to the monitoring facet 21 via the illumination channel 27. Via the illumination channel 27, the transfer facet 21 is transferred into the object field 8 in such a way that the illumination channel 27 impinges on either the entire object field 8 or a partial field of the object field 8, depending on the grouping selection of the individual mirrors ES which belong as an individual mirror group to the respective transfer facet 21. Such a grouping of the individual mirrors ES, resulting for example in the edge contour of the transfer facet 21 according to FIG. 6, is not illustrated in FIG. 6.

FIG. 6 additionally illustrates a monitoring device 28 of the illumination optical unit 11. The monitoring device 28 includes a spatially resolving monitoring sensor 29, which is embodied as a PSD, CMOS or CCD array with a multiplicity of sensor pixels, for example 10,000 x 10,000 sensor pixels. The spatially resolving monitoring sensor 29 can also have a significantly smaller number of sensor pixels, for example 10 x 10, 100 x 100 or 1000 x 1000. An aspect ratio of the number of pixels that is different from one is also possible. In general, a quadrant detector can also be used as monitoring sensor 29.

The monitoring device 28 furthermore includes a satellite facet 30 in the form of, for example, exactly one individual mirror or else a plurality of selected individual mirrors of the transfer facet mirror 6. The satellite facet 30 is independently actuator-tiltable by actuator about tilt axes parallel to the coordinates x and y.

FIG. 6 shows a monitoring light channel 31 from the light source 2 or the intermediate focus 5a via the satellite facet 30, the illumination specification facet 25, which simultaneously guides the illumination channel 27 according to FIG. 6, to a point of incidence or incidence region 32 on the monitoring sensor 29. A typical diameter of the point of incidence of the monitoring light channel 31 on the monitoring sensor 29 can be 1 mm.

The object field 8 has a longer field extension along the x-field dimension and a shorter field extension along the y-field dimension. The monitoring sensor 29 is arranged at a distance from the object field 8 along the x-field dimension and is located to the right of the shorter object field side of the object field 8 in the embodiment illustrated in FIG. 6. The monitoring sensor 29 can be arranged in the object plane 9; however, this is not mandatory. The monitoring sensor 29 can also be arranged at a distance from the object plane 9, for example – in comparison with the reticle 12 – more closely adjacent to the illumination specification facet mirror 7 or alternatively further away from the latter.

On account of the guidance via the same illumination specification facet 25, the satellite facet 30 is assigned to the transfer facet 21 highlighted in FIG. 6, which transfer facet therefore constitutes a monitoring transfer facet 21. This assignment involves an orientation of the satellite facet 30 in such a way that monitoring light, in this case the illumination light 3 generated by the light source 2, is guided from the light source 2, which then simultaneously constitutes a monitoring light source, via the satellite facet 30 and the illumination specification facet 25 highlighted in FIG. 6 as the illumination specification facet to be monitored, along the monitoring light channel 31 to the monitoring sensor 29.

Tiltings drx, dry of the illumination specification facet 25 which guides both the illumination channel 27 and the monitoring light channel 31 simultaneously lead to a displacement of the illumination channel 27 and of the monitoring light channel 31, namely to displacements dx along the x-coordinate and dy along the y-coordinate. The respective displacement dx, dy on the monitoring sensor 29 is a measure of the tilting dry, drx of the illumination specification facet 25 to be monitored about tilt axes parallel to the coordinate axes x and y. Accordingly, dy=f(drx) and dx=f(dry) hold true.

From the displacements dx, dy – measurable by way of the monitoring sensor 29 – between a target point of incidence 32_{S} – predetermined for example in the context of a calibration process – and the respectively measured actual point of incidence 32_{I} of the monitoring light channel 31 on the monitoring sensor 29, it is thus possible to deduce actual tiltings dry and drx of the monitored illumination specification facet 25.

When monitoring the illumination specification facets 25 of the illumination specification facet mirror 7 with the aid of the monitoring device 28, the following procedure can be adopted:

Firstly, satellite facets 30 are assigned to illumination specification facets 25 to be monitored. This can include assignment of the satellite facets 30 to transfer facets 21 which, firstly via the transfer facet 21 and the illumination channel 27 used in the projection exposure and secondly via the satellite facet 30 and the monitoring light channel 31, cause light to impinge on the same illumination specification facet 25 to be monitored.

Depending on the constraints of the assignment step, the satellite facet 30 can be closely adjacent to the monitoring transfer facet 21 assigned thereto. A maximum distance that is specifiable here can be for example the typical dimension of a monitoring transfer facet 21. An assignment can be effected for example with the constraint that the satellite facet 30 to be assigned is present on the same individual mirror unit 26 as in any case a plurality of individual mirrors ES of the monitoring transfer facet 21 to be assigned. It is also possible to use a multiple of the typical dimension of a monitoring transfer facet for the method as long as the spatial relationship between monitoring transfer facet and satellite mirror is sufficiently well known. A group of individual mirrors can therefore also be used as monitoring transfer facet 21. As an desirable feature, a greater distance between the satellite facet 30 and the monitoring transfer facet 21 assigned thereto in turn allows the monitoring sensor 29 to be able to be integrated into the scanner further away from the reticle 12.

After the assignment has been effected, the monitoring light, i.e. for example the illumination light 3, is guided along the monitoring light channel 31 via the respective satellite facet 30 and the assigned illumination specification facet 25 and an actual point of incidence 32ᵢ of the monitoring light channel 31 on the monitoring sensor 29 is measured in a spatially resolved manner. The actual point of incidence 32_{I} is subsequently compared with the predetermined target point of incidence 32_{S}.

This comparison takes place with the aid of an evaluation device 33 of the illumination optical unit 11. The evaluation device 33 is signal-connected to a central control device 34 of the projection exposure apparatus 1.

Depending on the comparison result of the monitoring method, compensatory countermeasures can be initiated, for example. This can be effected via the control device 34. Insofar as displacements of the points of incidence can be attributed to thermal drifts, especially thermal or mechanical compensation measures can also be implemented.

FIG. 7 shows a further embodiment of a monitoring device 35, which can be used as an alternative or in addition to the monitoring device 28 in a corresponding embodiment of the illumination optical unit 11 of the projection exposure apparatus 1. Components and functions corresponding to those which have already been explained above with reference to FIGS. 1 to 6, and for example with reference to FIG. 6, bear the same reference signs and will not be discussed in detail again.

The illumination optical unit 11 according to FIG. 7 is illustrated as a specular reflector. What are shown by way of example are, in a manner guided via individual mirrors ES of the illumination specification facet mirror 7, chief rays 36 and also marginal rays 37 delimiting an illumination angle distribution towards one side and marginal rays 38 delimiting it towards the other side. This is illustrated in the fundamentally schematic depiction according to FIG. 7 by the fact that the chief rays 36 meet in a centre of the entrance pupil 12a of the illumination optical unit 11. Accordingly, the marginal rays 37 firstly and 38 secondly meet in the beam path of the illumination light 3 downstream of the object field 8 at opposite marginal points of the entrance pupil 12a.

The illumination specification facet mirror 7 is arranged at a distance from the entrance pupil plane 12b of the projection optical unit 10, not illustrated in FIG. 7. The entrance pupil 12a of the projection optical unit 10, since it lies in the beam path downstream of the object field 8, is not accessible as an arrangement plane for the illumination specification facet mirror 7.

FIG. 7 furthermore illustrates, in a manner delimited in each case by two individual rays, two illumination channels 27₁and 27₂ used for illuminating the reticle 12. The illumination channel 27₁ is delimited by one of the chief rays 36 and one of the marginal rays 37. The illumination channel 27₁ is guided, proceeding from the intermediate focus 5a, via a transfer facet 21₁ and an illumination specification facet 25₁ to the object field 8. The illumination channel 27₂, which is in turn delimited by a chief ray 36 and by a marginal ray 38 assigned to the opposite illumination angle, is guided via a transfer facet 21₂ and an illumination specification facet 25₂ to the object field 8.

The transfer facets 21₁, 21₂ are formed from a group of individual mirrors ES of the transfer facet mirror 6. For example, 14x6 individual mirrors are selected in the illustration. Other groupings are possible as well, for example groupings having a few to several hundred of the individual mirrors.

The illumination specification facet 25₁ is formed from 2x2 individual mirrors ES of the illumination specification facet mirror 7. In contrast thereto, the illumination specification facet 25₂ is formed from 4x4 individual mirrors ES of the illumination specification facet mirror 7. Depending on the image shape and scale of a plasma image of the light source 2, it is also possible to assemble the illumination specification facets from other numbers or groupings of individual mirrors; for example 3x3 individual mirrors, 5x5, 6x6 or 7x7. It is furthermore possibly expedient to use non-square groups, such as 3x4, 3x5, 4x5, 4x6, 4x7, 5x7 or 6x7 individual mirrors. In the case shown in FIG. 7, the illumination specification facet 25₂is significantly larger than the illumination specification facet 25₁.

The monitoring device 35 according to FIG. 7 has a monitoring light source 39 separate from the illumination light source 2. This monitoring light source can be embodied as a laser diode, for example.

The monitoring light source 39 is embodied such that, in principle, illumination of the entire transfer facet mirror 6 is possible by way of this light source. A wavelength conversion screen 40 is arranged in the beam path of the monitoring light source 39.

The monitoring light source 39 can be a monochromatic laser diode. The wavelength conversion screen 40 can be a phosphor screen, for example a screen comprising YAG aluminium phosphor.

The monitoring device 35 has two monitoring sensors 29₁ and 29₂, which are arranged at a distance on both sides of the object field 8 in the direction of the x-coordinate, i.e. perpendicular to the object displacement direction y of the projection exposure apparatus 1. Furthermore, it is also possible to arrange further monitoring sensors 29ᵢ at a distance from one another in the x-direction in order thus to increase the effectively usable sensor area of the monitoring device 35 and to measure more illumination specification facets simultaneously. Furthermore, it is also possible to position exactly one monitoring sensor 29 at a distance from the object field 8 in the object displacement direction y.

A monitoring light channel 31 is illustrated in FIG. 7 between the wavelength conversion screen 40, a satellite facet 30, designed as an individual mirror ES on the transfer facet mirror 6, the illumination specification facet 25₂ and the monitoring sensor 29₂ of the monitoring device 35.

On account of the impingement on the same illumination specification facet 25₂, the monitoring light channel 31 illustrated in FIG. 7 and the satellite facet 30 impinged on by this channel are assigned to the illumination channel 27₂ and thus to the monitoring transfer facet 21₂ and the illumination specification facet 25₂ to be monitored.

As already explained above in association with the embodiment according to FIG. 6, tiltings drx, dry of the illumination specification facet 25₂ are transformed into displacements dy, dx of the point of incidence 32 of the monitoring light channel 31 on the monitoring sensor 29₂.

Suitable tilt angle assignments of the individual mirrors ES on the facet mirrors 6 and 7 can ensure that the monitoring light 41 of the monitoring light source 39 does not undesirably impinge on the object field 8.

With reference to FIG. 8, a description is given below of a further embodiment of the illumination optical unit 11 and a monitoring device 42, which can be used as an alternative or in addition to the monitoring devices 28, 35 explained above. Components and functions corresponding to those which have already been explained above with reference to FIGS. 1 to 7, and for example with reference to FIGS. 6 and 7, bear the same reference signs and will not be discussed in detail again.

Components or functional units of the illumination optical unit 11 which are illustrated in FIG. 8 are the intermediate focus 5a, the transfer facet mirror 6, the illumination specification facet mirror 7 and the in this case arcuate object field 8. The schematic, perspective illustration in FIG. 8 shows exemplary arrangements of the individual mirrors ES of, firstly, the transfer facet mirror 6 and, secondly, the illumination specification facet mirror 7.

Two transfer facets 21₁ and 21₂each constructed from a group of 18 individual mirrors ES are highlighted on the transfer facet mirror 6. The assignment of the individual mirrors ES to the respective transfer facets 21₁, 21₂ is such that an envelope of these transfer facets 21₁, 21₂ is adapted in the shape thereof to the arc shape of the object field 8. Illumination channels not illustrated in greater detail guide the illumination light from the intermediate focus 5a firstly via the transfer facet 21₁ and an illumination specification facet 25₁assigned to the illumination specification facet mirror 7 and also via the transfer facet 21₂ and an illumination specification facet 25₂ assigned to the illumination specification facet mirror 7 in a manner superimposed on one another for illuminating in each case the entire object field 8. The assigned illumination specification facets 25₁, 25₂each include four individual mirrors ES in a 2x2 arrangement. Other NxM arrangements of the individual mirrors ES are also possible, where N and M are each regularly in the range of between 1 and 10.

A monitoring light source 43 of the monitoring device 42 is embodied for generating monitoring light 41₁, 41₂ and 41₃ of in each case different wavelengths. The monitoring light 41₁, for example of a medium wavelength, proceeds from a source location 44₁ of the monitoring light source 43 adjacent to the intermediate focus 5a and is guided along a monitoring light channel 31₁ via a satellite facet 30₁, the illumination specification facet 25₂ to a point of incidence 32₁on the monitoring sensor 29₁. The satellite facet 30₁is thus assigned to the illumination specification facet 25₂ to be monitored.

The monitoring light source 43 furthermore generates monitoring light 41₂ which is of a shorter wavelength in comparison with monitoring light 41₁ and which is guided along a monitoring light channel 31₂ from a source location 44₂, once again adjacent to the intermediate focus 5a, to a satellite facet 30₂ and the illumination specification facet 25₁to a point of incidence 32₂ on the monitoring sensor 29₂. The satellite facet 30₂ is assigned to the illumination specification facet 25₁ to be monitored.

For further monitoring of an individual mirror ES₃ on the illumination specification facet mirror 7, a third monitoring light channel 31₃illustrated in FIG. 8 is used, which proceeds from a source location 44₃, once again adjacent to the intermediate focus 5a. Monitoring light 41₃ proceeding from this third source location 44₃ has a wavelength greater than the wavelengths of the monitoring light 41₁ and 41₂, and so the three different wavelengths of the monitoring light 41ᵢ proceeding from the source locations 44ᵢ are spectrally discriminable via the monitoring device 42.

The monitoring light channel 31₃passes from the source location 44₃ to a further satellite facet 30₃ on the transfer facet mirror 6 via the individual mirror ES₃ to be monitored on the illumination specification facet mirror 7 to a further point of incidence 32₃ on the monitoring sensor 29₂. The satellite facet 30₃ is assigned to the individual mirror ES₃ to be monitored. In contrast to the mirror groups ES₁ and ES₂, ES₃ is not impinged on by light which is to be imaged into the reticle 8. Such a configuration is useful in order to measure an individual mirror such as ES₃ in a targeted manner in terms of its tilt angle behaviour, independently of scanner operation, since exactly one image 32₃ is imaged on the sensor by this mirror. In contrast thereto, in cases 32₁ and 32₂, in this example 4 (2x2) image superimpositions of the images of 21₁ and 21₂ are present on the monitoring sensors 29. The measured images 32₁ and 32₂ are thus averaged over the tilt angle deviations of the mirror groups 25₁ and 25₂involved.

The monitoring sensors 29ᵢ of the monitoring device 42 can be embodied in a spectrally selective fashion, so that these monitoring sensors 29₁, 29₂ can determine, by way of the wavelength of the monitoring light 41ᵢ, which point of incidence 32ᵢ pertains to which monitoring light channel 31ᵢ. Especially parallel processing of an evaluation of the points of incidence 21ᵢ is possible via the monitoring device 42, so that the steps explained above in connection with the monitoring method “guiding monitoring light 41ᵢ, measuring a target point of incidence 32ᵢ and comparing the actual point of incidence 32ᵢ with a predetermined target point of incidence” can be carried out in parallel.

A spectral selectivity or colour decomposition by way of the monitoring sensors 29ᵢ allows a plurality of superimposed images to be recorded at the same time.

The monitoring light source 43 can be an RGB light source. The number of monitoring light channels 31ᵢ each having different monitoring light wavelengths can also be greater than three and can be for example in the range of between three and 20 or even greater. In principle, monitoring light 41ᵢ of a different wavelength can be used for each illumination specification facet 25ᵢ to be monitored, so that even all the illumination specification facets 25ᵢ can be detected simultaneously using a correspondingly spectrally discriminating monitoring sensor 29. Groups of monitoring light channels 41ᵢ each having the same wavelength, which belong to monitoring light channels 31ᵢ whose target points of incidence on the monitoring sensor 29 differ spatially to a sufficient extent, can also be formed, and so for example with the use of three wavelengths of the monitoring light 41 and 300 illumination specification facets 25ᵢ to be monitored, 100 illumination specification facets can in each case be monitored using the same wavelength of the monitoring light 41.

Especially in the case of the monitoring device 42, the monitoring sensors 29₁, 29₂ can act as CMOS sensors with a coloured Bayer matrix adapted to the wavelengths of the monitoring light source 43. Bayer matrices are known for example from the technical article “Review of Bayer Pattern Color Filter Array (CFA) demosaicing with new quality assessment algorithms” by R.A. Maschal Jr., et al., ARL-TR-5061, January 2010.

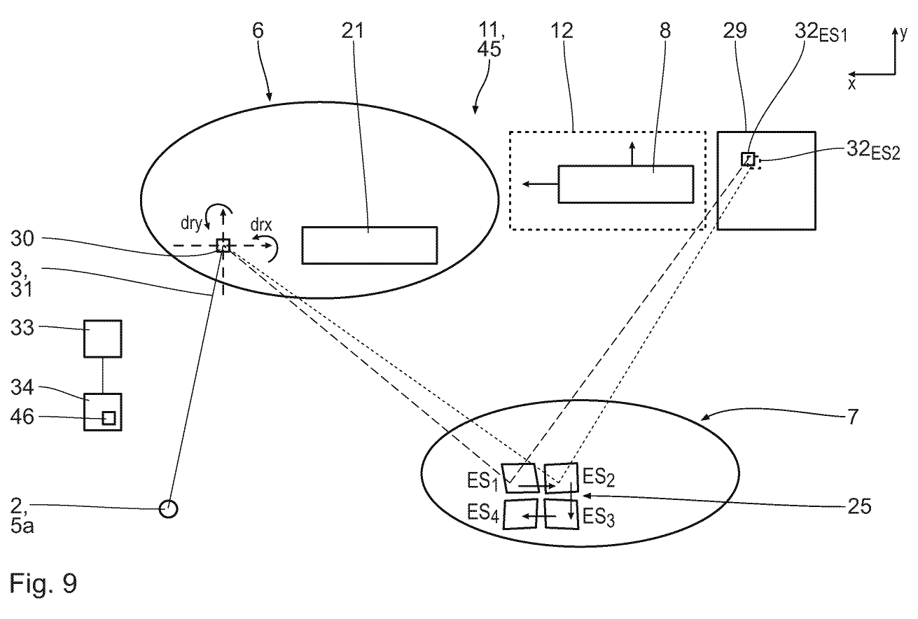

FIG. 9 shows, in an illustration comparable to FIG. 6, a further embodiment of a monitoring device 45, which can be used as an alternative or in addition to one of the monitoring devices explained above. Components and functions corresponding to those which have already been explained above with reference to FIGS. 1 to 8, and for example with reference to FIG. 6, bear the same reference signs and will not be discussed in detail again.

In the case of an illumination setting which is intended to be monitored via the monitoring device 45, an illumination specification facet 25 includes four individual mirrors ES₁ to ES₄, which grouped together form the illumination specification facet 25, in accordance with, for example, the illumination specification facets 25ᵢ of the embodiment according to FIG. 8.

In the case of the monitoring device 45, the satellite facet 30 is embodied as actuator-tiltable by tilt angles drx and dry in a manner controlled via the control device 34 of the monitoring device 45, analogously to what has been explained above for example in connection with the illumination specification facet 25 of the monitoring device 28 according to FIG. 6. The control device 34 includes a monitoring scanning unit 46, which is signal-connected to the actuator system of the satellite facet 30 used via the monitoring device 45.

When the monitoring light 3 is guided along the monitoring light channel 31, the monitoring scanning unit 46 controls the satellite facet 30 in such a way that all four individual mirrors ES₁ to ES₄ of the illumination specification facet 25 are scanned during the monitoring process of this illumination specification facet 25, which is illustrated in FIG. 9 by arrows between the individual mirrors ES₁ to ES₄.

According to the progress of the scanning step, points of incidence 32_{ES1} to 32_{ES4} assigned to the respective individual mirrors ES₁ to ES₄ arise, of which two locations of incidence 32_{ES1} and 32_{ES2}, assigned to the individual mirrors ES₁ and ES₂, are illustrated in FIG. 9. On the basis of these respectively measured points of incidence 32_{ESi}, a comparison with the corresponding target points of incidence can then be carried out using the monitoring method for monitoring all individual mirrors ESᵢ of the illumination specification facet 25.

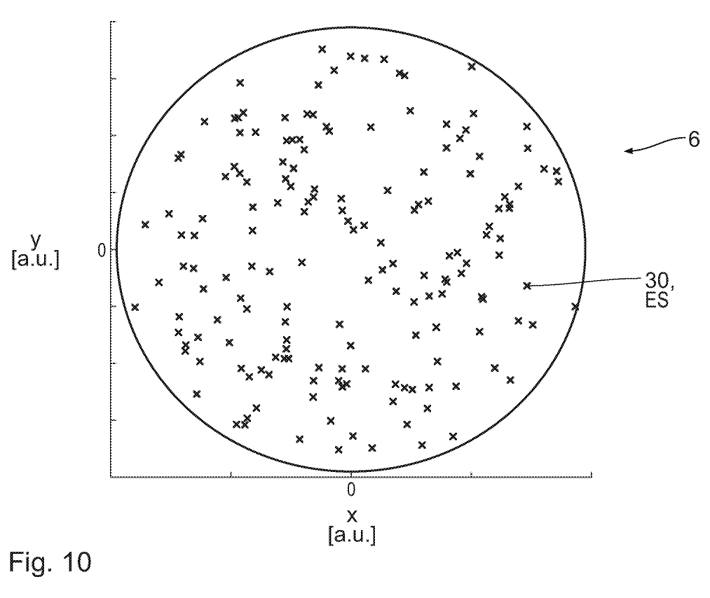

FIG. 10 illustrates how many individual mirrors ES are available as satellite facets 30 in the case of a typical illumination setting used in the projection exposure. A plan view of the transfer facet mirror 6 is illustrated, wherein those individual mirrors ES which are used for the set illumination setting are highlighted by an x symbol. With respect to these used individual mirrors ES, unused individual mirrors ES are present with practically uniform distribution over an entire surface of the transfer facet mirror 6, and can be used as satellite facets 30 in the context of one of the monitoring methods explained above. The number of individual mirrors ES usable as satellite facets 30 is regularly greater than the number of illumination specification facets 25 to be monitored, so that, in principle, all illumination specification facets used for an illumination setting can be monitored with regard to their current tilt position via the monitoring methods described above.

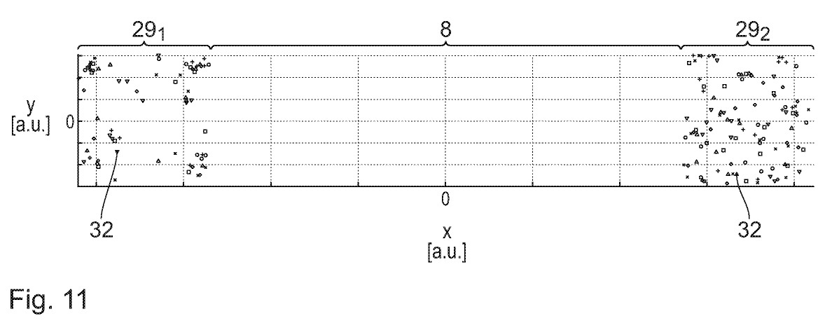

FIG. 11 shows by way of example the result of a parallel measurement, for example with the aid of a monitoring device configured in the same manner as the monitoring device 42, which can be produced with a larger number of different monitoring light wavelengths 41ᵢ. The points of incidence 32 respectively assigned to a monitoring light wavelength are illustrated by different symbols on the monitoring sensors 29₁ and 29₂. The points of incidence 32 assigned to different light wavelengths 41ᵢ are partially superimposed on one another. A spectral selectivity of the monitoring device 42, as explained above, can take effect here.

FIG. 11 shows in a plan view an in this case rectangular object field 8 between sensor areas of the two monitoring sensors 29₁ and 29₂. An x-extension of the sensor areas can be in the range of between 10% and 100% of an x-extension of the object field, for example 25% to 75%. A y-extension of the sensor areas of the monitoring sensors 29₁, 29₂ is regularly larger than a y-extension of the object field actually used for the current exposure and can comprise for example a y-extension corresponding to an entire y-scan course over the object field 8, or a multiple thereof; for example 200% or 500%. This means that the monitoring sensor 29ᵢ enlarged in this way can also be realized at a distance from the object field.

The sensor areas of the monitoring sensors 29ᵢ can be embodied as rectangular and for example square.

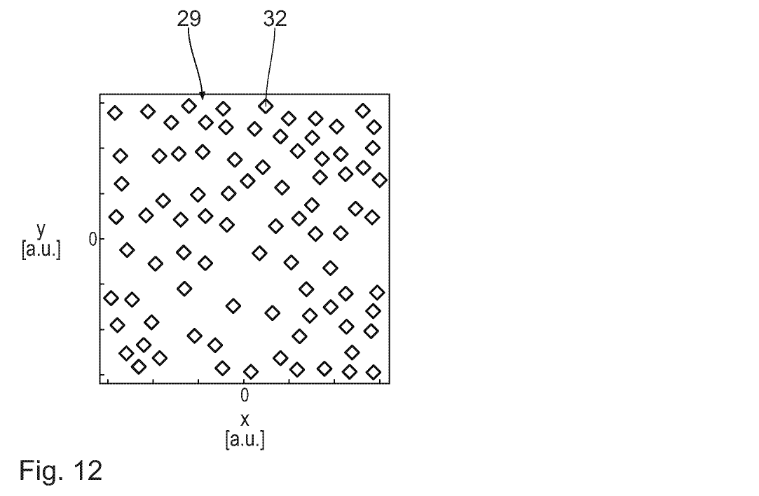

FIG. 12 shows, in an illustration similar to FIG. 11, a distribution of about 100 points of incidence 32 on the sensor area of one of the monitoring sensors 29 of one of the above-described embodiments of the monitoring device. This arrangement of the points of incidence 32 has a minimum distance between respectively predetermined target points of incidence of different monitoring light channels on the monitoring sensor 29, so that these points of incidence 32 can be distinguished even if the respective actual points of incidence deviate from the target points of incidence on account of tiltings of the monitored illumination specification facets 25.

Using a corresponding assignment algorithm, an assignment of the satellite facets 30 to the illumination specification facets 25 to be monitored in each case can be achieved which ensures a corresponding spatial distribution of the points of incidence 32 with sufficient minimum distance between two adjacent target points of incidence.

FIGS. 13 and 14 show a further embodiment of a monitoring device 47, which can be used instead of the monitoring devices described above. Components and functions corresponding to those which have already been explained above with reference to FIGS. 1 to 12, and for example with reference to FIGS. 6 to 12, bear the same reference signs and will not be discussed in detail again.

In the case of the monitoring device 47, a monitoring light source 48 is embodied as a light source grid with individual sources 49 arranged in an NxM grid. FIGS. 13 and 14 illustrate a 6x6 grid of individual sources 49.

With the aid of such a light source grid, the monitoring device 47 in parallel processing enables monitoring of tilt positions of a plurality of individual mirrors ES of an illumination specification facet 25 to be monitored with the same monitoring result that has been described above in connection with FIG. 9 in the context of sequential scan processing.

FIGS. 13 and 14 show for illustration purposes a monitoring light channel leading from a centre of the light source grid of the monitoring source 48 via a satellite facet 30 and an illumination specification facet 25 with a total of 6x6 individual mirrors ES to a point of incidence 32 on the monitoring sensor 29. The illumination specification facet 25 is embodied as a 6x6 grid of individual mirrors ES in the embodiment according to FIGS. 13 and 14.

FIG. 13 shows the situation in which all individual sources 49 of the monitoring light source 48 are activated. The illustration additionally shows the situation in which the illumination specification facet 25 is arranged in a pupil plane of the illumination optical unit, so that a grid of corresponding source images 50 of the individual sources 49 is generated on the illumination specification facet 25. The pose of this grid of source images 50 can be determined in the context of a calibration measurement. The distances between the individual sources 49 can be dimensioned such that the source images 50 are each assigned to exactly one individual mirror ES of the illumination specification facet.

When all 36 individual sources 49 are activated, in the situation according to FIG. 13, in any case in principle all 36 individual mirrors ES of the illumination specification facet 25 to be monitored can be monitored with regard to their points of incidence via the monitoring light channel 31 to the sensor 29. Parallel monitoring is thus possible, as an alternative to the scanning variant of monitoring via the monitoring scanning unit 46 as illustrated above in association with FIG. 9.

For measuring single individual mirrors ES of the illumination specification facet 25 to be monitored, the operating situation according to FIG. 14 can be established, in which exactly one selected individual source 49 of the monitoring light source 48 is activated, whereas all the other 35 individual sources 49 are deactivated. Via the thus resulting monitoring light channel 31 via the satellite facet 30 and the individual mirror ES at the location of the source image 50 of the activated individual source 49, tilt angle monitoring of this assigned individual mirror ES is then possible.

When comparing the respective actual point of incidence with the respectively predetermined target point of incidence, it is possible to use techniques known in optics as cross-correlation techniques. Such a cross-correlation can be used for determining a displacement of a specific point of incidence 32 or else for parallel determination of displacements of a plurality of points of incidence 32 by determining and evaluating a cross-correlation signal of a recording of the monitoring sensor 29 with a corresponding plurality of points of incidence 32ᵢ, each pertaining to a monitoring light channel 31ᵢ.

In parallel with the monitoring of the illumination optical unit 11 using a monitoring device described above, it is possible to carry out a used projection exposure for imaging the reticle 12 onto the wafer 19 using a preset illumination setting.

In order to produce a microstructured component, for example a highly integrated semiconductor component, for example a memory chip, with the aid of the projection exposure apparatus 1, firstly the reticle 12 and the wafer 19 are provided. Subsequently, a structure on the reticle 12 is illuminated by the illumination light 3 using the illumination optical unit 11 and is projected onto a light-sensitive layer on the wafer 19 using the projection optical unit of the projection exposure apparatus 1. By developing the light-sensitive layer, a microstructure is then produced on the wafer 19 and the microstructured or nanostructured component is produced therefrom.

The component produced can be a microchip, for example a memory chip.

What is claimed is:

1. An illumination optical unit, comprising:
a transfer facet mirror comprising a plurality of transfer facets configured to guide illumination light from an illumination light source along an illumination light beam path via illumination channels specified by the transfer facets;
an illumination specification facet mirror comprising a plurality of actuator-tiltable illumination specification facets configured to superimposedly guide the illumination light to an object field via the illumination channels, each illumination channel having one of the transfer facets and an assigned illumination specification facet, the transfer facets being imageable at least into portions of the object field; and
a monitoring device, comprising:
at least one spatially resolving monitoring sensor; and
at least one satellite facet of the transfer facet mirror,
wherein for each satellite facet:
the satellite facet is assigned to exactly one of the transfer facets so that the transfer facet constitutes a monitoring transfer facet; and
the satellite facet is configured so that monitoring light from a monitoring light source is guided via the satellite facet and one of the illumination specification facets, assigned to the monitoring transfer facet via the illumination channel, along a monitoring light channel to the monitoring sensor to monitor the illumination specification facet.

2. The illumination optical unit of claim 1, wherein the at least one satellite facet comprises a plurality of satellite facets.

3. The illumination optical unit of claim 1, wherein, for each satellite facet, the satellite facet is closely adjacent to the monitoring transfer facet assigned thereto.

4. The illumination optical unit of claim 1, wherein the object field has a longer field extension along a first field dimension and a shorter field extension along a second field dimension perpendicular thereto, and the at least one monitoring sensor is arranged a distance from the object field along the first field dimension.

5. The illumination optical unit of claim 1, wherein the monitoring light source comprises a light source separate from an illumination light source, and the monitoring light is guided along a monitoring light beam path adjacent to the illumination channels via at least one of the satellite facets and its assigned illumination specification facet to be monitored.

6. The illumination optical unit of claim 1, wherein the monitoring light has a plurality of wavelengths, and the monitoring sensor is wavelength-selective.

7. The illumination optical unit of claim 1, wherein each transfer facets is subdivided into a plurality of transfer individual mirrors, and/or each illumination specification facet is subdivided into a plurality of illumination specification individual mirrors.

8. The illumination optical unit of claim 7, wherein the at least one satellite facet is actuator-tiltable, and the monitoring device comprises a monitoring scanning unit signal-connected to an actuator system configured to tilt the at least one satellite facet.

9. The illumination optical unit of claim 1, wherein the monitoring light source comprises a light source grid adapted to a grid of illumination specification individual mirrors, and each illumination specification individual mirror defines an illumination specification facet.

10. The illumination optical unit of claim 1, wherein the at least one satellite facet comprises a plurality of satellite facets, and each satellite facet is closely adjacent to the monitoring transfer facet assigned thereto.

11. The illumination optical unit of claim 1, wherein:
the at least one satellite facet comprises a plurality of satellite facets, and each satellite facet is closely adjacent to the monitoring transfer facet assigned thereto;
the object field has a longer field extension along a first field dimension and a shorter field extension along a second field dimension perpendicular thereto; and
the at least one monitoring sensor is arranged a distance from the object field along the first field dimension.

12. An optical system, comprising:
an illumination optical unit according to claim 1; and
a projection optical unit configured to image the object field into an image field.

13. An apparatus, comprising:
an optical system, comprising:
an illumination optical unit according to claim 1; and
a projection optical unit configured to image the object field into an image field; and
an illumination light source,
wherein the apparatus is a projection exposure apparatus.

14. An optical system, comprising:
an illumination optical unit according to claim 1; and
a monitoring light source.

15. An apparatus, comprising:
an optical system, comprising:
an illumination optical unit according to claim 1; and
a monitoring light source; and
an illumination light source,
wherein the apparatus is a projection exposure apparatus.

16. The apparatus of claim 15, further comprising a projection optical unit configured to image the object field into an image field.

17. A method for producing a microstructured component using a projection exposure apparatus comprising an illumination optical unit and a projection optical unit, the method comprising:
using the illumination optical unit to at least partially illuminate a reticle in an object field of the projection exposure apparatus;
using the projection optical unit to project at least one portion of the illuminated reticle onto a light-sensitive material in an image field of the projection exposure apparatus; and
developing the light-sensitive material,
wherein the illumination optical unit comprises an illumination optical unit according to claim 1.

18. The method of claim 17, wherein the projection exposure apparatus further comprises a monitoring light source.

19. A method, comprising:
providing an illumination optical unit according to claim 1;
for each satellite facet, assigning the satellite facet to an illumination specification facet to be monitored;
for each of at least one of the monitoring light channels, guiding monitoring light along the monitoring light channel via its respective satellite facet and its assigned illumination specification facet to be monitored;
for each of the at least one monitoring light channels, measuring an actual point of incidence of the monitoring light channel on the monitoring sensor; and
for each of the at least one monitoring light channels, comparing the actual point of incidence with a predetermined target point of incidence of the monitoring light channel.

20. The method of claim 19, wherein assigning each satellite facet to its illumination specification facet to be monitored comprises:
maintaining a minimum distance between predetermined target points of incidence of different monitoring light channels on the monitoring sensor; and/or
not exceeding a maximum distance between the satellite facet and its monitoring transfer facet.
